(19) United States
(12) Patent Application Publication
(10) Pub. No.: US 2026/0363013 A1
(43) Pub. Date: Nov. 12, 2026

(54) NOZZLE UNIT FOR SUBSTRATE PROCESSING APPARATUS AND SUBSTRATE PROCESSING APPARATUS INCLUDING THE SAME

(71) Applicant: Samsung Electronics Co., Ltd., Suwon-si (KR)

(72) Inventors: Dongkyun Lim, Suwon-si (KR); Seungchul Kwon, Suwon-si (KR); Hyungmoo Lee, Suwon-si (KR)

(21) Appl. No.: 19/439,067

(22) Filed: Jan. 2, 2026

(30) Foreign Application Priority Data
May 12, 2025 (KR) 10-2025-0061462

(51) Int. Cl. H10P 72/00; G03F 7/16; H10P 72/78

(52) U.S. Cl. CPC H10P 72/0414; G03F 7/162; H10P 72/78

(57) ABSTRACT

The present disclosure relates to a nozzle unit for a substrate processing apparatus. An example nozzle unit includes an ionization unit configured to ionize an incoming first gas and a discharge unit configured to discharge the ion gas. The first gas is ionized while flowing between a plurality of electrodes spaced apart from each other in the ionization unit, and a second gas flows with increasing velocity along a flow path with a decreasing cross-sectional area in the discharge unit, and as the flow velocity increases, pressure decreases and the ion gas is discharged to the outside.

### CROSS-REFERENCE TO RELATED APPLICATION

This application claims priority under 35 U.S.C. §119 to Korean Patent Application No. 10-2025-0061462, filed on May 12, 2025, in the Korean Intellectual Property Office, the disclosure of which is incorporated by reference herein in its entirety.

### Background

In a semiconductor or display manufacturing process, a process of applying a photoresist (PR) onto a substrate may be included. This photoresist application process is generally performed by spin coating, and for this purpose, a spin coater device may be used. In a substrate processing apparatus of the related art, a photoresist nozzle for spraying a photoresist onto a substrate, a rinse nozzle for spraying a cleaning solution, and a gas nozzle for supplying a purge gas such as nitrogen may be used. Recently, with the miniaturization and high integration of semiconductor devices, requirements for photoresist materials and coating processes are becoming more stringent, and various technologies are being developed to improve interlayer adhesion and ensure coating uniformity.

### SUMMARY

The present disclosure relates to a nozzle unit capable of improving the reactivity of a surface of a substrate by supplying an ionized gas source in advance from a spin coating nozzle, and a substrate processing apparatus including the same.

In addition, the present disclosure relates to a nozzle unit capable of minimizing the impact on a process and a device by providing an ionized gas source at an equipment level, and minimizing equipment and replacement costs through replacement at a nozzle unit level, and a substrate processing apparatus including the same.

The problems to be solved by the technical spirit of the present disclosure are not limited to the problems mentioned above, and other problems not mentioned will be clearly understood by those skilled in the art from the following description.

In some embodiments, a nozzle unit for a substrate processing apparatus includes an ionization unit configured to ionize an incoming first gas; and a discharge unit configured to discharge an ion gas, which is the first gas ionized in the ionization unit, to the outside as the pressure decreases as a second gas is introduced and the speed increases, wherein the first gas is ionized while flowing between a plurality of electrodes spaced apart from each other in the ionization unit, and a second gas flows with increasing velocity along a flow path with a decreasing cross-sectional area in the discharge unit, and as the flow velocity increases, pressure decreases and the ion gas is discharged to the outside.

In some embodiments, a substrate processing apparatus includes a stage supporting a substrate, a nozzle arm arranged on an upper side of the stage, a cleaning nozzle head attached to the nozzle arm, and a nozzle unit coupled to the cleaning nozzle head, wherein the nozzle unit includes an ionization unit configured to ionize an incoming first gas, and a discharge unit configured to discharge an ion gas ionized from the first gas in the ionization unit to the outside as a pressure decrease occurs due to an increase in velocity of an incoming second gas, wherein the first gas is ionized while flowing between a plurality of electrodes spaced apart from each other in the ionization unit, the second gas flows with increasing velocity along a flow path with decreasing cross-sectional area in the discharge unit and as the flow velocity increases, pressure decreases and the ion gas is discharged to the outside, the cleaning nozzle head sprays a cleaning solution onto the substrate, and the nozzle unit sprays the ionized gas onto a surface of the substrate to perform surface activation treatment.

In some embodiments, a substrate processing apparatus includes a stage supporting a substrate, a nozzle arm arranged on an upper side of the stage and capable of moving up and down and rotating, a cleaning nozzle head attached to the nozzle arm and configured to spray a cleaning solution onto the substrate, and a nozzle unit coupled to the cleaning nozzle head, wherein the nozzle unit includes an ionization unit and a discharge unit, wherein the ionization unit includes an outer cylinder, an intermediate cylinder, and an inner cylinder arranged in a concentric structure, a first electrode plate formed on an inner surface of the outer cylinder, a second electrode plate and a third electrode plate formed on an outer surface and an inner surface of the intermediate cylinder, respectively, a fourth electrode plate formed on an outer surface of the inner cylinder, and a first gas inlet for introducing a hydrocarbon-based gas between the outer cylinder and the intermediate cylinder, and the first electrode plate, the second electrode plate, the third electrode plate, and the fourth electrode plate are arranged to cross each other to form a discharge path, wherein the discharge unit includes a plurality of tapered structures connected to a lower end of the ionization unit and having gradually decreasing cross-sectional areas, a low-reactivity gas receiving unit formed on a side of the tapered structure and configured to receive a low-reactivity gas recombined during the ionization process, and a second gas inlet extending into the inner cylinder to introduce an inert gas into the inner cylinder, wherein each of the tapered structures includes a second opening located in an upper portion thereof and a first opening located in a lower portion thereof, and a diameter of the first opening is less than the diameter of the second opening, a hydrocarbon series gas introduced through the first gas inlet is ionized by a discharge occurring between electrode plates having different polarities in the ionization unit, and a velocity of an inert gas introduced through the second gas inlet increases while passing through the tapered structure, and thus, surrounding pressure is decreased, thus causing the ionized gas to be sprayed onto a surface of the substrate to perform surface activation treatment.

### BRIEF DESCRIPTION OF THE DRAWINGS

Embodiments will be more clearly understood from the following detailed description taken in conjunction with the accompanying drawings.

FIG. 1 is a perspective view schematically showing an example of a nozzle unit.

FIG. 2 is an example partial perspective view schematically showing the nozzle unit of FIG. 1.

FIG. 3 is an example schematic cross-sectional view showing the nozzle unit of FIG. 1.

FIG. 4 is an example schematic diagram of longitudinal section of the nozzle unit of FIG. 1.

FIG. 5A is an enlarged view of an example of a discharge unit of FIG. 1.

FIG. 5B is an enlarged view of a modified example of the discharge unit.

FIGS. 6A, 6B, 6C, 6D, 6E, and 6F, are example schematic diagrams of longitudinal sections of nozzle units.

FIG. 7 is a schematic diagram of an example of a substrate processing apparatus equipped with a nozzle unit,

FIG. 8 is a flowchart showing an example of a substrate processing method.

### DETAILED DESCRIPTION

Hereinafter, embodiments of the present disclosure will be described in detail with reference to the attached drawings. The same reference numerals are used for the same components in the drawings, and redundant descriptions thereof are omitted.

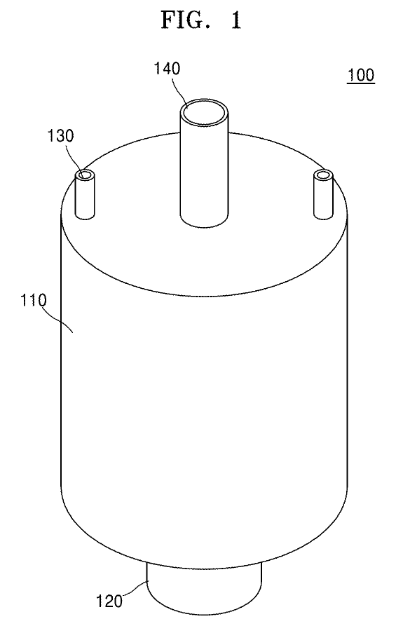

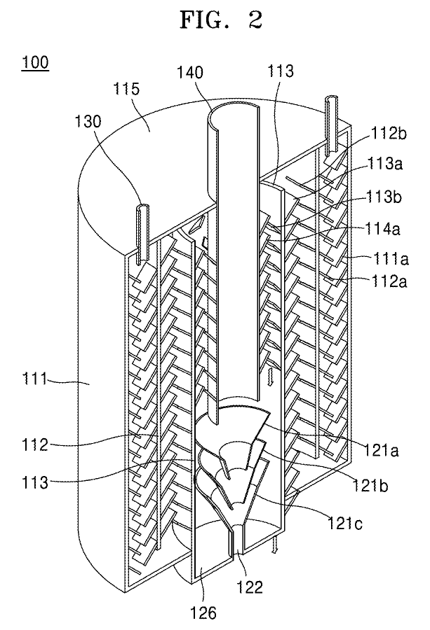

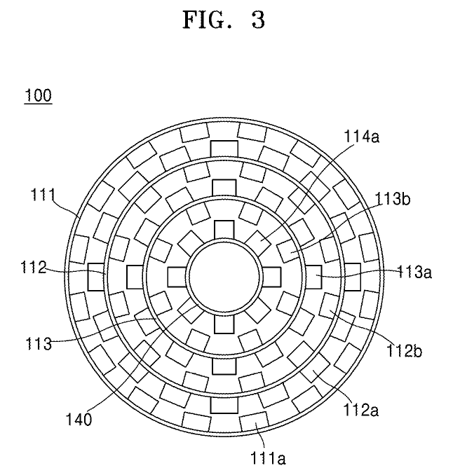

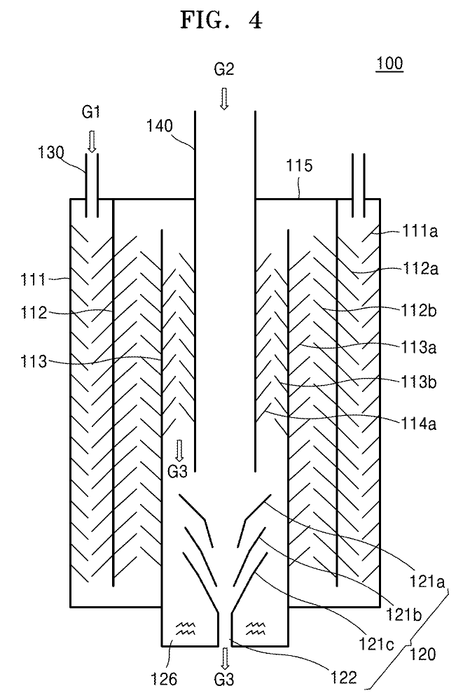

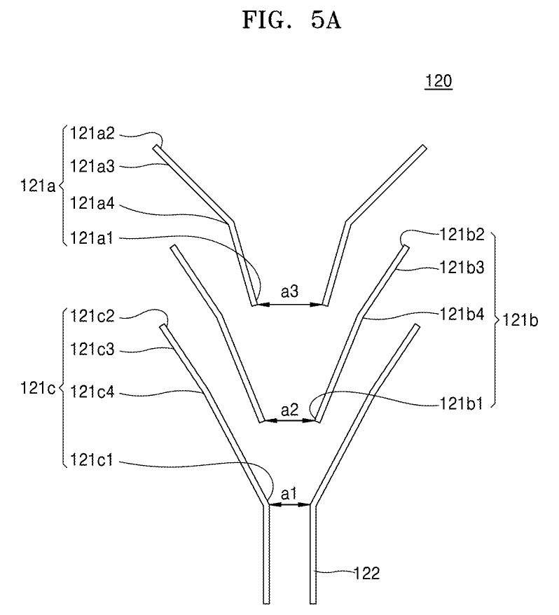

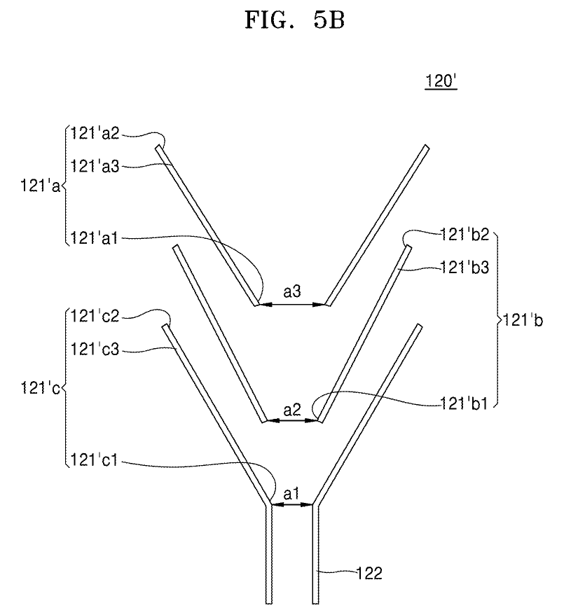

FIG. 1 is a perspective view schematically showing an example of a nozzle unit 100, FIG. 2 is an example partial perspective view schematically showing the nozzle unit 100 of FIGS. 1, and 3, is an example schematic cross-sectional view showing the nozzle unit 100 of FIG. 1. In addition, FIG. 4 is an example schematic diagram of longitudinal section of the nozzle unit 100 of FIGS. 1, and 5A, is an enlarged view of an example of a discharge unit 120 of FIG. 1.

Referring to FIGS. 1-5A, the nozzle unit 100 may include an ionization unit 110 that ionizes a first gas G1 that flows in, and the discharge unit 120 that discharges an ion gas G3, which is generated by ionizing the first gas G1 in the ionization unit 110, to the outside due to a reduction in pressure resulting from an increase in the speed of a second gas G2 flowing in.

According to one aspect of the present disclosure, the first gas G1 may be ionized by flowing between a plurality of electrode plates spaced apart from each other in the ionization unit 110. At this time, the plurality of electrode plates may include a first electrode plate 111a, a second electrode plate 112a, a third electrode plate 112b, a fourth electrode plate 113a, a fifth electrode plate 113b, and a sixth electrode plate 114a. Meanwhile, the second gas G2 flows along a flow path with decreasing cross-sectional area within the discharge unit 120 and the flow velocity increases, and as the flow velocity increases, the pressure decreases, so that the ion gas G3 may be discharged to the outside.

The first gas G1 may be ionized by electric discharge (arcing) occurring between multiple electrode plates. Specifically, when a high voltage is applied between electrode plates having different potentials, the intensity of the electric field may exceed the dielectric breakdown strength of the gas, causing a discharge. During this discharge process, gas molecules may collide with electrons and be separated into ions and radicals. In particular, in a structure in which the electrode plates are arranged alternately, a discharge path is continuously formed, and thus, efficient ionization is enabled. In addition, the special shape of the electrode plates (turbine blades, sawtooth, zigzag, etc.) may increase the discharge area, further improving the ionization efficiency.

The discharge process of the ion gas G3 is based on Bernoulli's principle. When the second gas G2 passes through the tapered structure of the discharge unit 120, the velocity of the fluid may increase due to the flow path with a decreasing cross-sectional area. According to Bernoulli's principle, an increase in the velocity of the fluid is accompanied by a decrease in pressure. The pressure reduction forms a negative pressure in a region adjacent to the ionization unit 110, which causes the first gas G1 ionized to be sucked in a direction of the discharge unit 120. The inclined section of the tapered structure, particularly the inclined bent unit, optimizes the flow of fluid to maximize the Bernoulli effect.

In this way, the present disclosure may efficiently transfer the ionized gas to a surface of a substrate without an additional driving section or vacuum pump by combining the gas ionization mechanism using electric discharge and the motorless discharge system using the Bernoulli principle. In addition, during the ionization process, because the recombined gas with low reactivity naturally settles in a low-reactivity gas receiving unit 126 due to the difference in density, there is an advantage in that only highly reactive ion gases may be selectively discharged.

Hereinafter, each component of the nozzle unit 100 will be described in detail.

First, the ionization unit 110 may include a plurality of cylinders arranged in a concentric structure. As an example, the ionization unit 110 may include a first cylinder 111, a second cylinder 112, and a third cylinder 113. The first cylinder 111 may be an outer cylinder located at the outermost position, the second cylinder 112 may be an intermediate cylinder located between the first cylinder 111 and the third cylinder 113, and the third cylinder 113 may be an inner cylinder located at the innermost position.

The ionization unit 110 may further include a plurality of electrode plates formed on at least one of the inner and outer surfaces of the plurality of cylinders. As an example, a first electrode plate 111a may be formed on an inner surface of the first cylinder 111, a second electrode plate 112a may be formed on an outer surface of the second cylinder 112, and a third electrode plate 112b may be formed on an inner surface of the second cylinder 112. In addition, a fourth electrode plate 113a may be formed on an outer surface of the third cylinder 113, and a fifth electrode plate 113b may be formed on an inner surface of the third cylinder 113.

In some embodiments, the first cylinder 111, which is the outermost cylinder among the plurality of cylinders, may have the first electrode plate 111a only on the inner surface thereof. The electrode plates of adjacent cylinders may be arranged alternately to form a discharge path. That is, the first electrode plate 111a and the second electrode plate 112a, the third electrode plate 112b and the fourth electrode plate 113a, and the fifth electrode plate 113b and the sixth electrode plate 114a may each form a discharge path.

Adjacent cylinders may have different polarities. In some embodiments, the first cylinder 111 may act as an anode, and the second cylinder 112 may act as a cathode. In this case, the first electrode plate 111a formed on the inner surface of the first cylinder 111 becomes an anode, and the second electrode plate 112a and the third electrode plate 112b formed on the outer surface and the inner surface of the second cylinder 112, respectively, become cathodes. The third cylinder 113 acts as an anode again, and the fourth electrode plate 113a and the fifth electrode plate 113b formed on the outer and inner surfaces of the third cylinder 113 also act as anodes. In addition, a second gas inlet 140 acts as a cathode, and the sixth electrode plate 114a formed on an outer surface of the second gas inlet 140 also acts as a cathode.

In some embodiments, the first cylinder 111 may act as a cathode and the second cylinder 112 may act as an anode. In this case, the polarity of the electrode plates formed in each cylinder is also determined according to the polarity of the corresponding cylinder. In some embodiments, an AC voltage may be applied to the cylinders. When an AC voltage is applied, the polarity of each cylinder and electrode plate may change periodically to further improve the discharge efficiency.

In addition, the sixth electrode plate 114a may be formed on the outer surface of the second gas inlet 140. As shown in FIG. 4, the fifth electrode plate 113b and the sixth electrode plate 114a may be alternately arranged to form an additional discharge path inside the third cylinder 113. Through this configuration, ionization may be efficiently performed even inside the third cylinder 113.

The ionization unit 110 may further include an insulation unit 115 installed between the first cylinder 111 and the second cylinder 112. The insulation unit 115 may form an upper surface of the ionization unit 110. The insulation unit 115 may provide electrical insulation between the first cylinder 111 and the second cylinder 112 having different polarities, thereby creating a stable discharge environment. The insulation unit 115 may include ceramic, quartz, alumina, or other electrically insulating materials, which may have excellent durability and chemical stability even in a high-voltage environment. The installation of such the insulation unit 115 may prevent leakage current between electrodes and improve discharge efficiency. In particular, when the first cylinder 111 acts as an anode and the second cylinder 112 acts as a cathode, the insulation unit 115 may optimize ionization efficiency by preventing unnecessary discharge between the first cylinder 111 and the second cylinder 112 while allowing intended discharge between the electrode plates.

Referring to FIG. 4, a plurality of electrode plates may be arranged in a diagonal direction in a cross-sectional view. The diagonal arrangement provides the following advantages. First, because the discharge path between the electrode plates is formed in a zigzag shape, the discharge length increases, so that the ionization efficiency may be improved. Second, the diagonally arranged electrode plates induce the flow of the first gas G1 so that the gas moves along a spiral path within the ionization unit 110. This increases the residence time of the gas, so that the ionization efficiency may further be improved. Third, the diagonally arranged electrode plates may efficiently utilize the space between the cylinders while maintaining a constant interval between each other, so that the maximum ionization effect may be obtained within a limited space.

In particular, the first electrode plate 111a and the second electrode plate 112a, the third electrode plate 112b and the fourth electrode plate 113a, and the fifth electrode plate 113b and the sixth electrode plate 114a are arranged in an alternating manner, and thus, discharge may effectively occur between electrode plates of different polarities. The cross-sectional arrangement provides optimal conditions for plasma formation and is one of the key technical features of the present disclosure.

The cross-sections of the plurality of electrode plates may have various shapes. In some embodiments, the cross-sections of the plurality of electrode plates may have any one of a turbine blade shape, a sawtooth shape, a zigzag shape, a wave shape, a wedge shape, a pin shape, a needle shape, a mesh shape, and a bar shape. As shown in FIG. 3, in some embodiments, the plurality of electrode plates may have a turbine blade shape. This turbine blade shape may narrow the distance between the electrode plates while maximizing the overlapping area, thereby improving the discharge efficiency.

The nozzle unit 100 may further include a first gas inlet 130 that allows the first gas G1 to be introduced between the first cylinder 111 and the second cylinder 112. The first gas inlet 130 may be formed on an upper portion of the first cylinder 111 and may guide the first gas G1 into a space between the first cylinder 111 and the second cylinder 112.

In addition, the nozzle unit 100 may further include the second gas inlet 140 that extends into an inside of the third cylinder 113 to allow the second gas G2 to be introduced. The sixth electrode plate 114a may be arranged on an outer surface of the second gas inlet 140, and the fifth electrode plate 113b formed on the inner surface of the third cylinder 113 and the sixth electrode plate 114a formed on the outer surface of the second gas inlet 140 may be alternately arranged to form an additional discharge path.

Meanwhile, the discharge unit 120 may include at least one tapered structure into which the ion gas G3 is introduced from the ionization unit 110 and an outlet unit 122 through which ion gas G3 is discharged to the outside from the tapered structure. In some embodiments, the discharge unit 120 may include a first tapered structure 121a, a second tapered structure 121b, and a third tapered structure 121c. The plurality of tapered structures may be arranged spaced apart from each other.

Each tapered structure may include a first opening facing a direction in which the ion gas G3 is discharged to the outside, a second opening facing the first opening, and an inclined unit connecting the first opening and the second opening. Specifically, the first tapered structure 121a may include a first opening 121a1, a second opening 121a2, and an inclined unit 121a3, the second tapered structure 121b may include a first opening 121b1, a second opening 121b2, and an inclined unit 121b3, and the third tapered structure 121c may include a first opening 121c1, a second opening 121c2, and an inclined unit 121c3.

In some embodiments, the inclined unit of each tapered structure may be bent at least once in a direction toward the cylinder. Specifically, the inclined unit 121a3 of the first tapered structure 121a may include an inclined bent portion 121a4, the inclined portion 121b3 of the second tapered structure 121b may include an inclined bent portion 121b4, and the inclined portion 121c3 of the third tapered structure 121c may include an inclined bent portion 121c4. The inclined bent portions may effectively control the flow of fluid to maximize the Bernoulli effect.

The first opening of at least one tapered structure has a diameter that becomes less as it faces the outside where the ion gas G3 is placed. That is, a diameter a2 of the first opening 121b1 of the second tapered structure 121b may be less than a diameter a3 of the first opening 121a1 of the first tapered structure 121a, and a diameter a1 of the first opening 121c1 of the third tapered structure 121c may be less than the diameter a2 of the first opening 121b1 of the second tapered structure 121b.

The gradual diameter reduction of the tapered structures generates an important fluid dynamic effect based on Bernoulli's principle. When the second gas G2 passes through the tapered structures in sequence, the velocity of the fluid continuously increases as the cross-sectional area gradually decreases. According to Bernoulli's principle, an increase in the velocity of the fluid is accompanied by a decrease in the pressure in the corresponding region. In particular, the highest fluid velocity and the lowest pressure are formed near the first opening 121c1 of the third tapered structure 121c with the smallest diameter.

The low pressure region thus formed generates a pressure difference between the ionization unit 110 and the discharge unit 120. The pressure difference acts as a suction force that pulls the ion gas G3 generated in the ionization unit 110 toward the discharge unit 120. That is, the ion gas G3 naturally moves from the ionization unit 110 where the pressure is relatively high to the tapered structure region where the pressure is low, and this pressure gradient acts as a driving force for efficient discharge of the ion gas G3.

In this way, the design of the tapered structure according to the present disclosure may implement a motorless discharge system that may effectively discharge the ion gas G3 without an additional mechanical pump or motor. This may provide an important technical advantage of simplifying the structure of the device and increasing energy efficiency.

The discharge unit 120 may further include the low-reactivity gas receiving unit 126 formed on a side of the tapered structure to receive a low-reactivity gas recombined during the ionization process. The low-reactivity gas receiving unit 126 allows a recombined gas, which has a higher density than the ionized gas, to naturally settle and be separated. This may help the efficient discharge of the ionized gas.

According to some embodiments, the first gas G1 may include a hydrocarbon-based gas CₓH_{y}, hydrogen H₂, or a mixture thereof. Also, the second gas G2 may include an inert gas, for example, nitrogen N₂, argon Ar, or a mixture thereof.

The operating principle of the nozzle unit 100 is described as follows. First, the first gas G1 may be introduced into the ionization unit 110 through the first gas inlet 130. The first gas G1 that is introduced into the ionization unit 110 may be ionized by a discharge occurring between a plurality of electrode plates having different polarities. At the same time, the second gas G2 may be introduced into the third cylinder 113 through the second gas inlet 140. The second gas G2 may increase in speed as it passes through the tapered structure of the discharge unit 120, and thus, the surrounding pressure may decrease. Due to the pressure decrease, the first gas G1 that is ionized may be discharged to the outside through the discharge unit 120.

In some embodiments, the number of cylinders is limited to three, but as may be understood by those skilled in the art, the number of cylinders may be increased or decreased as needed. In addition, the number of tapered structures is not limited to three, and at least one tapered structure may be used.

FIG. 5B is an enlarged view of a modified example of the discharge unit. Referring to FIG. 5B, the discharge unit 120’ according to some embodiments may include a tapered structure without a bent unit in the inclined unit. Specifically, the first tapered structure 121'a may include a first opening 121'a1, a second opening 121'a2, and an inclined unit 121'a3, a second tapered structure 121'b may include a first opening 121'b1, a second opening 121'b2, and an inclined unit 121'b3, and the third tapered structure 121'c may include a first opening 121'c1, a second opening 121'c2, and an inclined unit 121'c3.

Unlike the embodiment illustrated in FIG. 5A, the inclined units of the tapered structures illustrated in FIG. 5B are not bent but have a straight shape. Such a straight-shaped inclined unit may also perform the function of increasing the velocity of the fluid and reducing the pressure according to the Bernoulli principle. The straight-shaped tapered structure has the advantage of being easy to manufacture and having a simple structure. However, the pressure reduction effect may be relatively low compared to a tapered structure having an inclined bent unit.

In some embodiments, a mixed configuration, in which some of the plurality of tapered structures have bent units as in FIG. 5A, and others have inclined units in a straight shape as in FIG. 5b, may be possible. For example, the first tapered structure may include an inclined bent unit, and the second and third tapered structures may have inclined units in a straight shape. Such a mixed configuration may be advantageous in controlling the flow of the fluid more precisely and in optimizing the pressure drop and the increase in the flow rate.

Even in the modified example illustrated in FIG. 5B, a diameter a2 of the first opening 121'b1 of the second tapered structure 121'b may be less than a diameter a3 of the first opening 121'a1 of the first tapered structure 121'a, and a diameter a1 of the first opening 121'c1 of the third tapered structure 121'c may be less than the diameter a2 of the first opening 121'b1 of the second tapered structure 121'b. The gradual decrease in diameter maximizes the Bernoulli effect, thereby promoting efficient discharge of the ion gas G3.

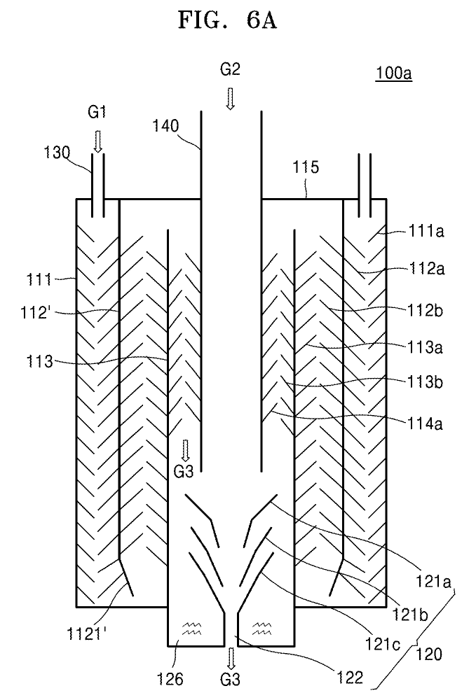

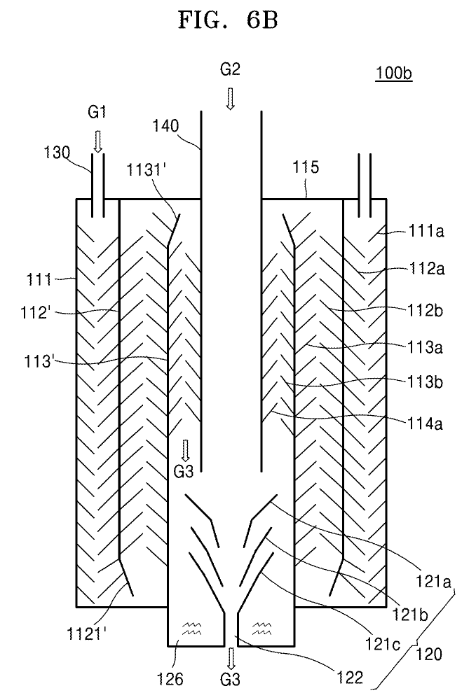

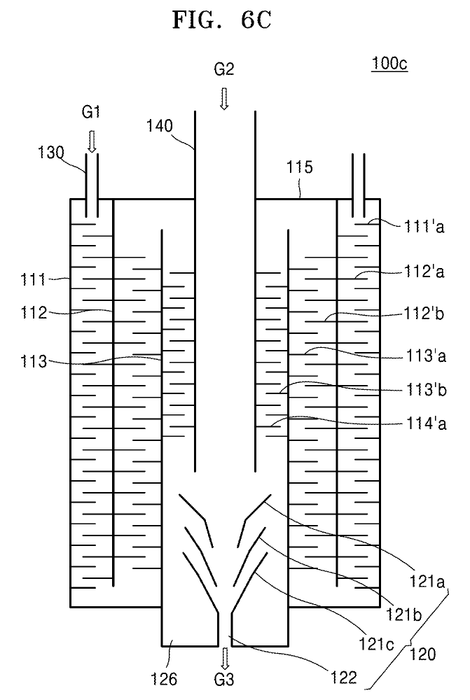

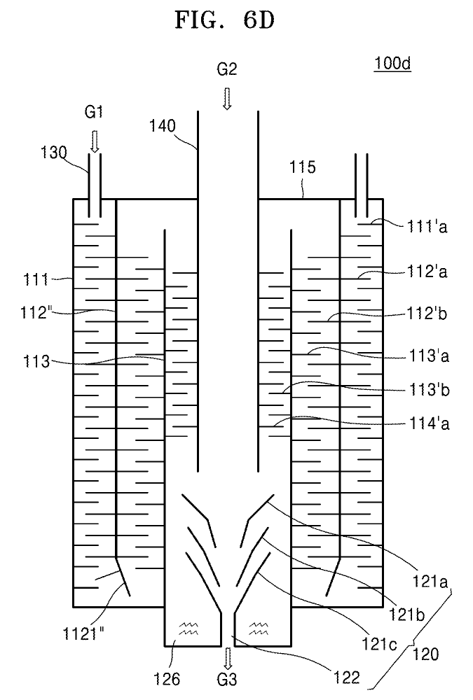

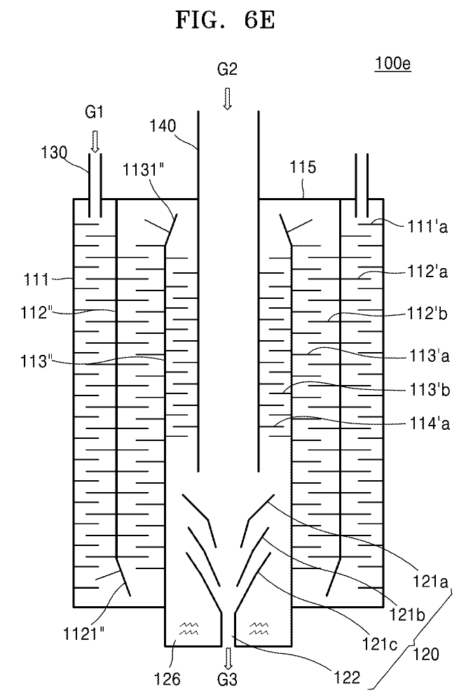

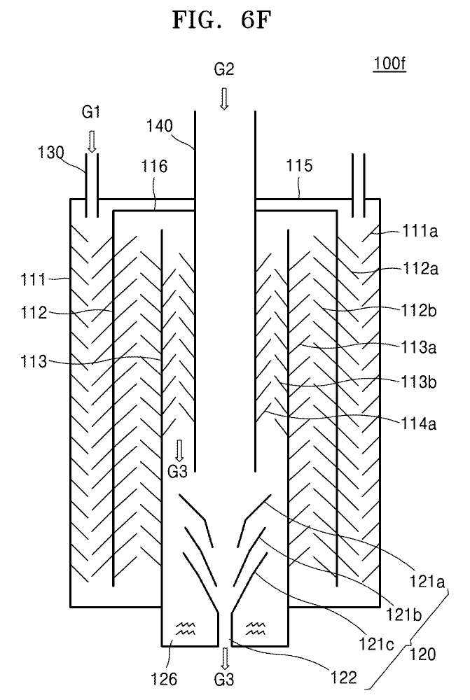

FIG. 6A is a cross-sectional view schematically illustrating an example of a nozzle unit 100a. Referring to FIG. 6A, the nozzle unit 100a according to some embodiments has the same configuration as the embodiment illustrated in FIG. 4, but differs in that one end of the second cylinder 112' is bent toward the center of the nozzle unit 100a.

Specifically, the lower end of the second cylinder 112' is bent toward the central axis to form a cylinder bent unit 1121'. The bending structure has the effect of changing the flow path of the first gas G1 within the ionization unit 110. The first gas G1 flows downward in a space between the first cylinder 111 and the second cylinder 112', and then, is induced to flow toward the center along the cylinder bent unit 1121' of the second cylinder 112'. This causes the first gas G1 to travel along a more complex path within the ionization unit 110, which may increase the residence time of the first gas G1 and improve the ionization efficiency.

In addition, the bend structure of the second cylinder 112' may effectively guide the ionized gas to the discharge unit 120. In particular, the gas ionized between the second cylinder 112' and the third cylinder 113 may be concentrated toward the center along the cylinder bent unit 1121' and efficiently introduced into the tapered structure of the discharge unit 120.

The cylinder bent structure has the advantage of allowing more efficient use of the internal space of the ionization unit 110 and more effective control of the flow of the ionized gas. In addition, a region formed by the cylinder bent unit 1121' may further improve the separation efficiency of the highly reactive ion and the low-reactive recombined gas by providing a space where the low-reactivity gas recombined during the ionization process may temporarily stay.

FIG. 6B is a schematic cross-sectional view showing an example of a nozzle unit 100b. Referring to FIG. 6b, the nozzle unit 100b according to some embodiments has the same configuration as the embodiment illustrated in FIG. 6A, but differs in that an upper end of the third cylinder 113' is bent toward the center of the nozzle unit 100b.

Specifically, the nozzle unit 100b illustrated in FIG. 6B not only has a lower end of the second cylinder 112' bent toward the central axis to form the cylinder bent unit 1121', but also has the upper end of the third cylinder 113' bent toward the central axis to form a cylinder bent unit 1131'. The bending structure at different upper and lower portions may make the flow of gas in the ionization unit 110 more complicated, which may greatly improve the ionization efficiency.

Through the bending of the lower end of the second cylinder 112' and the bending of the upper end of the third cylinder 113', the first gas G1 may flow along the following complex path. First, the first gas G1 flows downward in a space between the first cylinder 111 and the second cylinder 112', and is induced to flow toward the center along the cylinder bent unit 1121' of the second cylinder 112'. At the same time, the gas flowing into the space between the second cylinder 112' and the third cylinder 113' is initially induced toward the center by the cylinder bent unit 1131' of the upper end of the third cylinder 113' and then flows downward.

The folded structure at different upper and lower positions generates a vortex-shaped gas flow within the ionization unit 110, which maximizes the residence time of the first gas G1 and increases the opportunity for contact with the discharge region, thereby greatly improving the ionization efficiency. In addition, this structure may more effectively concentrate and guide the ionized gas to the discharge unit 120.

The bending structure of the upper end of third cylinder 113' may effectively collect ion gas from the upper end toward the center, and thus, there is the effect of increasing the ion concentration in the process of being discharged through the center. This results in only the more reactive ion gas being delivered to a surface of a substrate through the discharge unit 120.

In some embodiments, in FIG. 6A, only the second cylinder 112' is depicted as having a bent structure, and in FIG. 6B, the second cylinder 112' and the third cylinder 113' are depicted as having bent structures, but in some embodiments, at least one of the plurality of cylinders may have a bent structure. In addition, the bending angle and the bending position may be variously modified as needed.

FIG. 6C is a schematic cross-sectional view showing an example of a nozzle unit 100c. Referring to FIG. 6C, the nozzle unit 100c according to some embodiments has a similar configuration to the embodiment illustrated in FIG. 4, but differs in that the first to sixth electrode plates 111'a to 114'a are arranged in parallel and alternately with each other.

Specifically, in FIG. 6C, the first electrode plate 111'a, the second electrode plate 112'a, the third electrode plate 112'b, the fourth electrode plate 113'a, the fifth electrode plate 113'b, and the sixth electrode plate 114'a are all arranged vertically with respect to the central axis of each cylinder. This is in contrast to the electrode plates in FIG. 4, where the electrode plates are arranged diagonally.

In this vertical arrangement structure, the first electrode plate 111'a formed on the inner surface of the first cylinder 111 and the second electrode plate 112'a formed on the outer surface of the second cylinder 112 are arranged parallel to each other while facing each other in the horizontal direction. Likewise, the third electrode plate 112'b formed on the inner surface of the second cylinder 112, the fourth electrode plate 113'a formed on the outer surface of the third cylinder 113, the fifth electrode plate 113'b formed on the inner surface of the third cylinder 113, and the sixth electrode plate 114'a formed on the outer surface of the second gas inlet 140 are also arranged in parallel while facing each other in the horizontal direction.

The structure in which the electrode plates are arranged vertically has the following features and advantages. First, the manufacturing process may be simplified. The electrode plates in the horizontal direction are easy to process in a concentric shape when manufacturing a cylinder, and thus, it is easier to manufacture than complex diagonal structures. Second, because a gap between electrode plates is easy to maintain evenly, the discharge characteristics may be controlled more stably.

Discharge between vertically arranged electrode plates may be directly and uniformly performed. Because the distance between adjacent electrode plates is maintained constant, a uniform electric field is formed over the entire ionization unit 110, which may improve the consistency of ionization efficiency. In particular, while straight line path discharge occurs between electrode plates located at the same height, cross discharge may also occur between electrode plates located at different heights, and thus, a complex discharge network may be formed.

In addition, the vertically arranged electrode plate structure acts as a periodic obstacle to the flow of the first gas G1, which may hinder the flow of the gas and generate eddies to increase a residence time. This may ultimately contribute to improving the ionization efficiency.

In some embodiments, as in FIG. 4, the first gas G1 is ionized by generating a discharge between electrode plates having different polarities. The vertically arranged electrode plates are arranged alternately, so that the discharge path is evenly distributed throughout the ionization unit 110. The uniform discharge distribution may contribute to maximizing the ionization efficiency.

In some embodiments, FIG. 6C shows that all electrode plates are arranged vertically, but in other embodiments, various combinations are possible, such as some electrode plates being arranged vertically and others being arranged diagonally. In addition, the shape and size of each electrode plate may be modified in various ways as needed.

FIG. 6D is a schematic cross-sectional view showing an example of a nozzle unit 100d. Referring to FIG. 6D, the nozzle unit 100d according to some embodiments is similar to the embodiment illustrated in FIG. 6C in that the electrode plates are arranged vertically, but one end of a second cylinder 112" is bent toward the center of the nozzle unit 100d as in FIG. 6A.

Specifically, in the nozzle unit 100d illustrated in FIG. 6D, the first electrode plate 111'a, the second electrode plate 112'a, the third electrode plate 112'b, the fourth electrode plate 113'a, the fifth electrode plate 113'b, and the sixth electrode plate 114'a are all arranged in a vertical direction with respect to the central axis of each cylinder. The vertical arrangement structure facilitates the production of the cylinder, as in FIG. 6C, and may provide stable discharge characteristics by maintaining the gap between the electrode plates uniformly.

At the same time, a lower end of the second cylinder 112" is bent toward the central axis of the cylinder to form a cylinder bent unit 1121". This bent structure has the effect of changing the flow path of the first gas G1 within the ionization unit 110. The first gas G1 may flow downward in a space between the first cylinder 111 and the second cylinder 112", and then, be induced to flow toward the center along the cylinder bent unit 1121" of the second cylinder 112".

The above composite structure includes two major advantages. First, stable and efficient ionization is possible through uniform discharge characteristics between vertically arranged electrode plates. Second, the flow path of the first gas G1 may be made complicate through the bent structure of the second cylinder 112", thereby increasing the residence time and improving the ionization efficiency.

In particular, the combination of vertically arranged electrode plates and the bent cylinder structure may form a unique discharge and flow pattern. The vertical electrode plates generate a uniform discharge at each height, and the bent cylinder guides the flow of gas passing through the discharge region toward the center. This flow guidance mechanism allows the gas ionized by the discharge to naturally concentrate toward the discharge unit 120, thereby promoting efficient discharge of the ion gas.

In addition, a region formed by the cylinder bent unit 1121" of the second cylinder 112" provides a space where the low-reactivity gas recombined during the ionization process may temporarily stay, thereby improving the separation efficiency of the highly reactive ion and the low-reactivity recombined gas.

The configuration of the nozzle unit 100d may take advantage of both the ease of manufacturing the vertically arranged electrode plates and the improved ionization efficiency of the bent cylinder structure, thereby providing a practical and high-performance nozzle unit.

FIG. 6E is a schematic cross-sectional view showing an example of a nozzle unit 100e. Referring to FIG. 6E, the nozzle unit 100e according to some embodiments is different from the embodiment illustrated in FIG. 6D in that the electrode plates are arranged vertically and the lower end of the second cylinder 112" is bent, while additionally including a cylinder bent unit 1131" in which the upper end of the third cylinder 113" is bent toward the center of the nozzle unit 100e.

Specifically, in the nozzle unit 100e, similar to FIG. 6D, the first electrode plate 111'a, the second electrode plate 112'a, the third electrode plate 112'b, the fourth electrode plate 113'a, the fifth electrode plate 113'b, and the sixth electrode plate 114'a are all arranged in a vertical direction with respect to the central axis of each cylinder. In addition, the lower end of the second cylinder 112" may be bent in the direction of the central axis to form a cylinder bent unit 1121". In addition, the upper end of the third cylinder 113" may also be bent in the direction of the central axis to form a cylinder bent unit 1131".

The combination of the double-bent structure and vertically arranged electrode plates may create a very complicate gas flow pattern and discharge network. The first gas G1 first flows downward in the space between the first cylinder 111 and the second cylinder 112", and then flows toward the center along the cylinder bent unit 1121" of the second cylinder 112". At the same time, the gas flowing between the second cylinder 112" and the third cylinder 113" is initially induced toward the center by the cylinder bent unit 1131" of the upper end of the third cylinder 113" and then flows downward.

The bent structure at different upper and lower positions and the vertically arranged electrode plates may generate a strong eddy-shaped gas flow within the ionization unit. This may greatly improve the ionization efficiency by maximizing the residence time of the first gas G1 and maximizing the contact opportunity with the vertically arranged electrode plates.

In particular, while the vertically arranged electrode plates generate a uniform discharge at each height, the cylindrical bent structures at different upper and lower positions make complicate the flow of gas passing through the discharge region. The upper bent structure of the third cylinder 113" may effectively gather the ion gas from the upper end toward the center, and the lower bent structure of the second cylinder 112" may concentrate the ion gas again toward the discharge unit. The complicate flow control may increase the ion concentration and promote efficient discharge of the ion gas.

In addition, the spaces formed by the cylinder bent units 1121" and 1131" of the second cylinder 112" and the third cylinder 113" provide additional spaces where low-reactivity gases recombined during the ionization process may stay, thereby maximizing the separation efficiency of high-reactivity ions and low-reactivity recombined gases.

In some embodiments, the nozzle unit 100d has a configuration that may take advantage of both the ease of manufacturing vertically arranged electrode plates and the improved ionization efficiency of the double-bent cylinder structure arranged at different upper and lower positions, thereby implementing a nozzle unit that may provide the highest level of performance along with practicality of manufacturing.

FIG. 6F is a schematic cross-sectional view showing an example of a nozzle unit 100f. Referring to FIG. 6F, the nozzle unit 100f has a configuration similar to the embodiment illustrated in FIG. 4, but is different in that a connecting unit 116 is additionally provided.

Specifically, the connecting unit 116 serves to electrically connect the second cylinder 112 and the second gas inlet 140. Through this connecting unit 116, the second cylinder 112 and the second gas inlet 140 may have the same polarity. In some embodiments, when the second cylinder 112 acts as a cathode, the second gas inlet 140 connected by the connecting unit 116 also acts as a cathode.

The connecting unit 116 may include a metal material having excellent electrical conductivity and may be implemented in the form of a fixing bracket, a metal strap, or a conductive wire. This connecting unit 116 may further improve the ionization efficiency by maintaining the potential distribution inside the nozzle unit 100f evenly and providing a stable discharge environment.

In particular, the electrical connection between the second cylinder 112 and the second gas inlet 140 through the connecting unit 116 plays an important role in ensuring consistency of the discharge path. This may eliminate the potential difference between the third electrode plate 112b formed on the inner surface of the second cylinder 112 and the sixth electrode plate 114a formed on the outer surface of the second gas inlet 140, and thus, discharge may be induced to effectively occur mainly between the third electrode plate 112b and the fourth electrode plate 113a, and between the fifth electrode plate 113b and the sixth electrode plate 114a.

In addition, the connecting unit 116 may improve the electrical stability of the nozzle unit 100f so that the nozzle unit 100f may maintain a constant ionization performance even during long-term operation. This may provide an especially important advantage in applications that require high precision and reproducibility, such as semiconductor manufacturing processes.

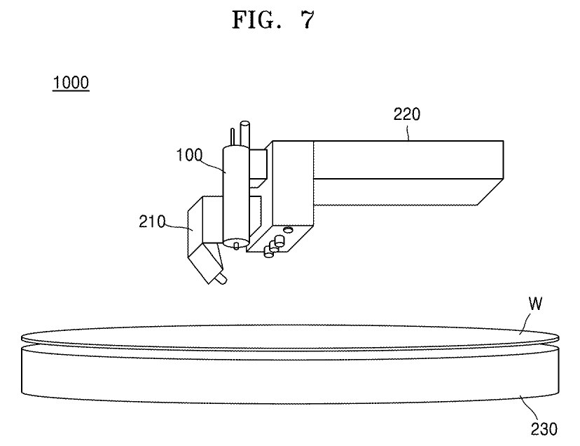

FIG. 7 is a schematic diagram showing an example of a substrate processing apparatus 1000 equipped with a nozzle unit. Referring to FIG. 7, the substrate processing apparatus 1000 may include a stage 230 supporting a substrate W, a nozzle arm 220 disposed on an upper side of the stage 230, a cleaning nozzle head 210 attached to the nozzle arm 220, and a nozzle unit 100 coupled to the cleaning nozzle head 210.

The stage 230 may include a rotation driving unit capable of horizontally supporting the substrate W and rotating the substrate W. The stage 230 may fix the substrate W using a vacuum chuck or an electrostatic chuck, and the rotation speed may be precisely controlled according to process requirements. The rotation of the substrate W may play an important role in uniformly distributing a coating material, a cleaning solution, an ionized gas, etc. onto a surface of the substrate W.

The nozzle arm 220 is placed above the stage 230 and may be configured to be moved in the X, Y, and Z-axis directions. In particular, the nozzle arm 220 may be moved radially from the center of the substrate W to an edge, and may also be moved up and down and rotated as needed. The multi-axis movement function enables optimized processing for substrates of various sizes.

The cleaning nozzle head 210 is attached to an end of the nozzle arm 220 and may include multiple nozzles for spraying various process solutions such as cleaning solution, photoresist, and developer on the surface of the substrate W. The cleaning nozzle head 210 may be configured by integrating various types of nozzles such as a photoresist nozzle, a rinse nozzle, and a nitrogen purge nozzle, and thus, various processes may be performed sequentially or simultaneously on the surface of the substrate W. The cleaning nozzle head 210 may include a precise flow rate control system to spray a process solution with nanometer-level precision.

The nozzle unit 100 is designed to be detachable from the cleaning nozzle head 210. The modular design allows for easy maintenance and replacement, and it is possible to replace only the nozzle unit 100 for upgrading or improving the performance of an existing substrate processing apparatus. An interface between the nozzle unit 100 and the cleaning nozzle head 210 may support fast and safe attachment/detachment using various connection methods (e.g., quick connector, bayonet method, clamp method, etc.).

As described above, the nozzle unit 100 includes an ionization unit 110 and a discharge unit 120, and may ionize the first gas and efficiently spray it onto the surface of the substrate W through the Bernoulli effect. The ionized gas exhausted from the nozzle unit 100 enhances the reactivity of the surface of the substrate W, thereby increasing the adhesion with a layer formed in the subsequent process and enabling uniform coating.

During operation, while the substrate W mounted on the stage 230 rotates, the nozzle arm 220 moves the cleaning nozzle head 210 and the nozzle unit 100 to an appropriate position on the surface of the substrate W. The cleaning nozzle head 210 sprays cleaning liquid, photoresist, etc. as needed, and the nozzle unit 100 sprays ionized gas to perform activation treatment on the surface of the substrate W. In this process, rotation of the substrate W may ensure uniformity of treatment.

The substrate processing apparatus 1000 of the present disclosure may exhibit excellent performance in a semiconductor manufacturing process, especially in an advanced process requiring fine pattern formation. The surface activation treatment through the nozzle unit 100 may effectively prevent problems such as undercuts and wiggles that may occur when forming nanometer-sized patterns, and may significantly improve process yield by improving interlayer adhesion.

In addition, the substrate processing apparatus 1000 of the present disclosure has excellent compatibility with existing equipment, and has the advantage of being able to improve performance simply by installing the nozzle unit 100 without additional equipment upgrades. This may be an effective solution that may improve process performance while reducing the total cost of ownership (TCO) of semiconductor manufacturing equipment.

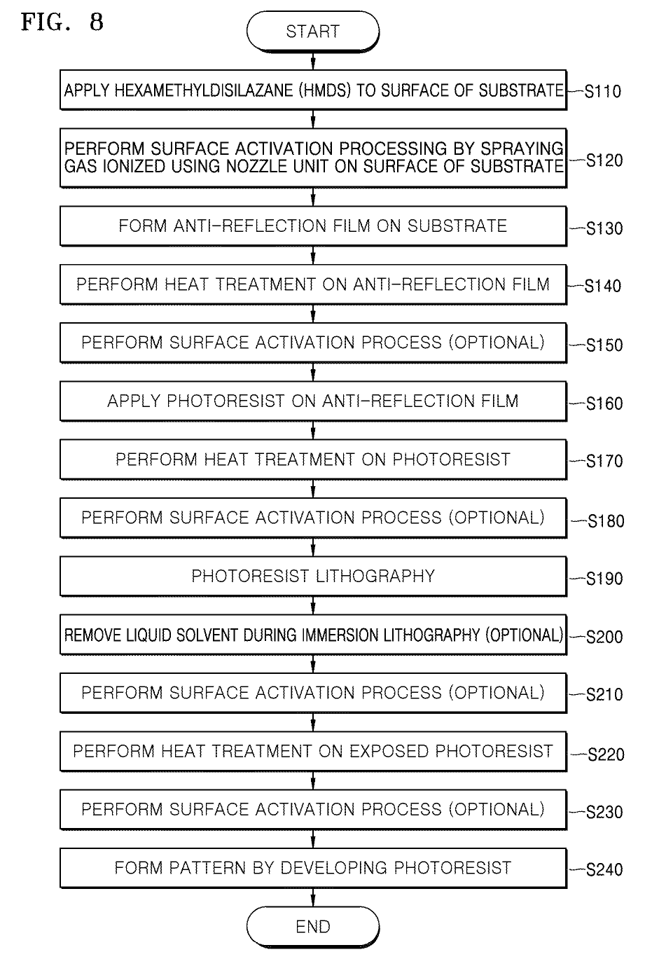

FIG. 8 is a flowchart schematically illustrating an example of a substrate processing method. Referring to FIG. 8, the substrate processing method includes a series of processes for forming a micro pattern in a semiconductor manufacturing process, and surface activation treatment may be selectively applied at each operation.

The substrate processing method may begin with an operation (S110) of applying an adhesion promoter (e.g., hexamethyldisilazane (HMDS)) to a surface of a substrate.

The adhesion promoter may improve the adhesion with subsequent layers by modifying the surface properties of the substrate. In the case of a silicon substrate, for example, HMDS may react with the silanol (Si-OH) group on the surface of the substrate to form a hydrophobic surface, thereby improving the adhesion with the photoresist. In addition, various adhesion promoters such as AP3000 and trimethylchlorosilane (TMCS) may be selectively used depending on the material of the substrate or process conditions. After applying the adhesion promoter, an operation (S120) of surface activation processing, which is a characteristic of the present disclosure, may be performed.

In this operation, ionized gas is sprayed onto the surface of the substrate using a nozzle unit. The nozzle unit ionizes a first gas (hydrocarbon series gas (CₓH_{y}), hydrogen (H₂), or a mixture thereof) by causing the first gas to flow between a plurality of electrodes, and allows a second gas (nitrogen (N₂), argon (Ar), or an inert gas including a mixture thereof) to flow through a flow path with a decreasing cross-sectional area, with increasing velocity and decreasing pressure, thereby enabling the ionized first gas to be effectively injected onto the surface of the substrate. In this process, the special design of the taper structure of the nozzle unit may maximize the Bernoulli effect to promote efficient discharge of the ion gas. Next, an operation (S130) of forming an anti-reflection film on the substrate may be performed.

The anti-reflection film prevents pattern distortion due to light reflection from the substrate during an exposure process. In this operation, a material for the anti-reflection film may be uniformly applied onto the substrate by spin coating. After the formation of the anti-reflection film, a heat treatment operation (S140) (commonly called 'Pre-bake' or 'Soft-bake') may be performed to remove the solvent and stabilize the film. This heat treatment may be generally performed at a temperature in the range of about 90 °C to about 250°C for about 30 seconds to about 120 seconds. After the heat treatment operation (S140), another surface activation operation (S150) may be optionally performed.

This operation may improve the reactivity of a surface of the anti-reflection film changed during the heat treatment process, thereby improving the adhesion with the subsequent photoresist layer. At this time, the first gas is effectively ionized by discharge generated between the plurality of cylinders and the plurality of electrode plates arranged in a concentric structure of the nozzle unit, and thus, the discharge path may be optimized to maximize the ionization efficiency. Next, an operation (S160) of applying a photoresist on the anti-reflection film may be performed.

The present disclosure is particularly effective for various types of photoresists, particularly metal-containing inorganic photoresists. Metal-containing inorganic photoresists are mainly used for extreme ultraviolet (EUV) lithography, and have higher sensitivity to EUV light than general organic photoresists, but may have an adhesion problem with a lower layer. The photoresist application is performed by spin coating, and a film of uniform thickness may be formed by precisely controlling the rotation speed, acceleration, time, etc. After the photoresist application, a heat treatment operation (S170) may be performed to remove the solvent and stabilize the physical properties.

This heat treatment may generally be performed at a temperature in a range of about 90 °C to about 150 °C for about 60 seconds to about 180 seconds. After the heat treatment, another surface activation operation (S180) may be optionally performed. This operation may change the chemical properties of the photoresist surface to improve sensitivity in the subsequent exposure process and promote uniform pattern formation. After the heat treatment operation (S170) or the surface activation operation (S180), additional processing operations may be performed before the photoresist exposure operation (S190).

These processes may include top photoresist baking through top photoresist baking (Top PR Bake), wafer edge exposure through wafer edge exposure (WEE), and backside processing through back side treatment (BST). The top photoresist baking is a process to further stabilize the top layer of the photoresist, and the wafer edge exposure is a process to selectively remove the photoresist at an edge of the wafer to prevent contamination in subsequent processes. The backside processing is a process to remove photoresist or contaminants that may remain on the back of the wafer. Subsequently, an operation (S190) of exposing the photoresist may be performed.

The exposure is a process of irradiating the photoresist with a specific pattern of light (DUV or EUV) through a mask. According to some embodiments, an immersion lithography method may be used during exposure. The immersion lithography method is a technology that increases a refractive index and thus improves resolution by filling a liquid medium (e.g., ultrapure water) between the photoresist and a final optical element of the exposure apparatus. This method may increase the effective numerical aperture by utilizing the principle that the refractive index of water (n=1.44) is higher than that of air (n=1.0). After exposure, an operation (S200) for removing the liquid medium may be performed, and in this process, damage may occur to a surface of the photoresist.

To repair the damage, a surface activation operation (S210) may be optionally performed. The ionized gas treatment may repair chemical and physical changes on the surface of the photoresist caused by contact with water during the immersion lithography, and promote uniform pattern formation. The exposed photoresist may promote a chemical reaction and stabilize the pattern through a post-exposure heat treatment operation (S220) (commonly called 'Post-Exposure Bake' or 'PEB').

The heat treatment may be performed at a temperature in a range of about 100°C to about 150°C for about 60 seconds to about 180 seconds. A surface activation operation (S230) may be optionally performed even after the heat treatment. The surface activation operation (S230) may improve the photoresist dissolution characteristics during the development process and enhance the pattern precision. Finally, an operation (S240) of developing the photoresist to form a pattern may be performed.

A desired pattern may be formed by selectively dissolving and removing the exposed region (in the case of positive photoresist) or the unexposed region (in the case of negative photoresist) using a developing solution. The developing process may be performed in various ways, such as dip, spray, and puddle. The nozzle unit used in the surface activation operation of the present disclosure has a structure including a plurality of cylinders and electrode plates, and the outermost cylinder has electrode plates formed only on the inner surface, and the electrode plates of the adjacent cylinders are arranged alternately to form a discharge path.

The cross-section of the electrode plates may have any one of a turbine blade shape, a sawtooth shape, a zigzag shape, a wave shape, a wedge shape, a pin shape, a needle shape, a mesh shape, and a bar shape, which maximizes the discharge area and improves the ionization efficiency. In addition, the discharge unit of the nozzle unit includes at least one tapered structure, and the tapered structure includes a second opening located at the top and a first opening located at the bottom, and the diameter of the first opening is less than the diameter of the second opening.

A low-reactivity gas receiving unit that receives a low-reactivity gas recombined during the ionization process is formed on a side of the tapered structure, thereby effectively separating highly reactive ions and low-reactivity recombined gases, thereby improving the surface activation efficiency. In this way, the substrate processing method of the present disclosure provides various advantages such as improved interlayer adhesion, prevention of pattern defects, and repair of surface damage by selectively performing surface activation treatment at various process stages.

In particular, in the EUV lithography process using a metal-containing inorganic photoresist, pattern defects such as undercuts or wiggles may be effectively prevented, and the process yield may be greatly improved. In addition, by repairing photoresist surface damage that may occur in the immersion exposure process, the precision and reliability of fine pattern formation may be greatly improved. While the present disclosure has been described with reference to the embodiments shown in the drawings, it will be understood by those of ordinary skill in the art that various changes in form and details may be made therein without departing from the spirit and scope of the present disclosure.

In some embodiments, a method of processing a substrate includes forming an anti-reflection film on the substrate, heat-treating the anti-reflection film, applying a photoresist on the anti-reflection film, heat-treating the photoresist, exposing the photoresist, heat-treating the exposed photoresist, and developing the photoresist to form a pattern. The method further includes a surface activation operation of spraying an ionized gas onto a surface of the substrate using a nozzle unit to enhance surface reactivity, where the surface activation operation is performed at least one time point among before the forming of the anti-reflection film, after the heat-treating of the anti-reflection film, after the heat-treating of the photoresist, after the exposing of the photoresist, and after the heat-treating of the exposed photoresist, where the nozzle unit includes a structure including a plurality of electrodes to ionize a first gas to form the ionized gas, and a flow path through which a cross-sectional area through which a second gas flows is reduced, where the surface activation operation includes ionizing the first gas in the nozzle unit, and spraying the ionized first gas onto the surface of the substrate by increasing the flow velocity and decreasing the pressure accordingly as the second gas flows through the flow path.

In some embodiments, the first gas may include a hydrocarbon series gas (CₓH_{y}), hydrogen (H₂), or a mixture thereof.

In some embodiments, the second gas may include an inert gas including nitrogen (N₂), argon (Ar) or a mixture thereof.

In some embodiments, the nozzle unit may include a plurality of cylinders arranged in a concentric structure and a plurality of electrode plates formed on at least one of inner and outer surfaces of the plurality of cylinders, where the electrode plates may be formed only on the inner surface of the outermost cylinder among the plurality of cylinders, and the electrode plates of adjacent cylinders may be arranged alternately to form a discharge path.

In some embodiments, among the plurality of cylinders, adjacent cylinders may have different polarities, and the first gas may be introduced between the outermost cylinder and a cylinder adjacent to the outermost cylinder, and the second gas may be introduced by extending into the innermost cylinder among the plurality of cylinders.

In some embodiments, a cross-section of the plurality of electrode plates may be any one of a turbine blade shape, a sawtooth shape, a zigzag shape, a wave shape, a wedge shape, a pin shape, a needle shape, a mesh shape, and a bar shape.

In some embodiments, the flow path of the nozzle unit may include at least one tapered structure through which the ionized gas flows, the tapered structure including a second opening located at the top and a first opening located at the bottom, and the diameter of the first opening may be less than the diameter of the second opening.

In some embodiments, a low-reactivity gas receiving unit that receives a low-reactivity gas recombined during the ionization process may be formed on a side of the tapered structure.

In some embodiments, the photoresist may include a metal-containing inorganic photoresist, and the surface activation operation may improve adhesion between the photoresist and a lower layer.

In some embodiments, the method may further include performing immersion exposure by filling a liquid medium between the photoresist and an optical element of an exposure device during the photoresist exposure and removing the liquid medium after the exposure, where the surface activation operation is performed after the removal of the liquid medium to repair surface damage of the photoresist.

In some embodiments, the method may further include applying an adhesion promoter (HMDS) to the surface of the substrate, where the surface activation operation may be performed after applying the adhesion promoter and before forming the anti-reflection film.

Accordingly, the scope of the present disclosure is defined not by the detailed description of the disclosure but by the appended claims. While the present disclosure has been shown and described with reference to embodiments thereof, it will be understood that various changes in form and details may be made therein without departing from the spirit and scope of the following claims.

What is claimed is:

1. A nozzle unit for a substrate processing apparatus, the nozzle unit comprising:
an ionization unit configured to ionize a first gas that flows between a plurality of electrodes spaced apart from each other, thereby generating an ion gas; and
a discharge unit configured to discharge the ion gas to an outside of the nozzle unit,
wherein the discharge unit includes a flow path, and a second gas is configured to be introduced into the discharge unit along the flow path, and
wherein the flow path has a cross-sectional area that decreases in a direction of the second gas being introduced in the discharge unit and causes the second gas to flow with increasing velocity along the flow path, thereby decreasing a pressure at the discharge unit and discharging the ion gas to the outside of the nozzle unit.

2. The nozzle unit of claim 1, wherein the ionization unit includes:
a plurality of cylinders arranged in a concentric structure; and
a plurality of electrode plates on at least one of an inner surface or an outer surface of each of the plurality of cylinders,
wherein an outermost cylinder among the plurality of cylinders has the plurality of electrode plates on the inner surface of the outermost cylinder, wherein the outer surface of the outermost cylinder is free of the plurality of electrode plates, and
wherein the plurality of electrode plates between two adjacent cylinders among the plurality of cylinders are arranged alternately to form a discharge path.

3. The nozzle unit of claim 2, wherein an end of at least one cylinder located inside the outermost cylinder among the plurality of cylinders is bent or curved toward a central axis of the plurality of cylinders.

4. The nozzle unit of claim 2, wherein the two adjacent cylinders among the plurality of cylinders have different polarities.

5. The nozzle unit of claim 2, wherein
a cross-section of the plurality of electrode plates has a turbine blade shape, a sawtooth shape, a zigzag shape, a wave shape, a wedge shape, a pin shape, a needle shape, a mesh shape, or a bar shape.

6. The nozzle unit of claim 2, comprising:
a first gas inlet, wherein the first gas is configured to flow through the first gas inlet into a space between the outermost cylinder and a cylinder adjacent to the outermost cylinder.

7. The nozzle unit of claim 6, comprising:
a second gas inlet extending into an innermost cylinder among the plurality of cylinders, wherein the second gas is configured to flow through the second gas inlet into the innermost cylinder.

8. The nozzle unit of claim 7, wherein
a second plurality of electrode plates are on an outer surface of the second gas inlet, a third plurality of electrode plates are on an inner surface of an innermost cylinder among the plurality of cylinders, and the third plurality of electrode plates and the second plurality of electrode plates are arranged alternately.

9. The nozzle unit of claim 2, wherein the discharge unit includes:
at least one tapered structure, wherein the ion gas is configured to flow from the ionization unit into the at least one tapered structure; and
an outlet unit, wherein the ion gas is configured to be discharged from the at least one tapered structure to the outside of the nozzle unit through the outlet unit,
wherein, based on the at least one tapered structure being a plurality of tapered structures, the plurality of tapered structures are spaced apart from each other, and
wherein each tapered structure of the plurality of tapered structures includes:
a first opening facing a second direction, wherein the ion gas is configured to be discharged to the outside of the nozzle unit in the second direction;
a second opening facing the first opening; and
an inclined unit connecting the first opening and the second opening, and
wherein the first opening of each tapered structure of the at least one tapered structure has a diameter that decreases toward the outside of the nozzle unit.

10. The nozzle unit of claim 9, wherein the inclined unit of each tapered structure of the plurality of tapered structures is bent or curved at least once in a direction toward an adjacent cylinder.

11. The nozzle unit of claim 9, wherein the discharge unit includes:
a low-reactivity gas receiving unit on a side of the at least one tapered structure to receive low-reactivity gas recombined in an ionization process.

12. The nozzle unit of claim 1, wherein the first gas includes a hydrocarbon series gas, hydrogen, or a mixture of hydrocarbon series gas and hydrogen.

13. The nozzle unit of claim 1, wherein the second gas includes an inert gas including nitrogen, argon, or a mixture of nitrogen and argon.

14. A substrate processing apparatus comprising:
a stage supporting a substrate;
a nozzle arm arranged on an upper side of the stage;
a cleaning nozzle head attached to the nozzle arm; and
a nozzle unit coupled to the cleaning nozzle head,
wherein the nozzle unit comprises:
an ionization unit configured to ionize a first gas that flows between a plurality of electrodes spaced apart from each other, thereby generating an ion gas; and
a discharge unit configured to discharge the ion gas to an outside of the nozzle unit,
wherein the discharge unit includes a flow path, and a second gas is configured to be introduced into the discharge unit along the flow path, and
wherein the flow path has a cross-sectional area that decreases in a direction of the second gas being introduced in the discharge unit and causes the second gas to flow with increasing velocity along the flow path, thereby decreasing a pressure at the discharge unit and discharging the ion gas to the outside of the nozzle unit,
wherein the cleaning nozzle head is configured to spray a cleaning solution onto the substrate, and
wherein the nozzle unit is configured to spray the ionized gas onto a surface of the substrate to perform surface activation treatment.

15. The substrate processing apparatus of claim 14, wherein the ionization unit comprises:
a plurality of cylinders arranged in a concentric structure; and
a plurality of electrode plates on at least one of an inner surface or an outer surface of each of the plurality of cylinders,
wherein an outermost cylinder among the plurality of cylinders has the plurality of electrode plates on the inner surface of the outermost cylinder, wherein the outer surface of the outermost cylinder is free of the plurality of electrode plates, and
wherein the plurality of electrode plates between two adjacent cylinders among the plurality of cylinders are arranged alternately to form a discharge path.

16. The substrate processing apparatus of claim 15, wherein the two adjacent cylinders among the plurality of cylinders have different polarities.

17. The substrate processing apparatus of claim 15, comprising:
a first gas inlet, wherein the first gas is configured to flow through the first gas inlet into a space between the outermost cylinder and a cylinder adjacent to the outermost cylinder; and
a second gas inlet extending into an innermost cylinder among the plurality of cylinders, wherein the second gas is configured to flow through the second gas inlet into the innermost cylinder.

18. The substrate processing apparatus of claim 15, wherein the discharge unit includes:
at least one tapered structure, wherein the ion gas is configured to flow from the ionization unit into the at least one tapered structure; and
an outlet unit, wherein the ion gas is configured to be discharged from the at least one tapered structure to the outside of the nozzle unit through the outlet unit,
wherein, based on the at least one tapered structure being a plurality of tapered structures, the plurality of tapered structures are arranged to be spaced apart from each other, and
wherein each tapered structure of the plurality of tapered structures includes:
a first opening facing a second direction, wherein the ion gas is discharged to the outside of the nozzle unit in the second direction;
a second opening facing the first opening; and
an inclined unit connecting the first opening and the second opening, and
wherein the first opening of each tapered structure of the at least one tapered structure has a diameter that decreases toward the outside of the nozzle unit.

19. The substrate processing apparatus of claim 18, wherein the discharge unit includes:
a low-reactivity gas receiving unit on a side of the at least one tapered structure to receive low-reactivity gas recombined in an ionization process.

20. A substrate processing apparatus comprising:
a stage supporting a substrate;
a nozzle arm on an upper side of the stage and configured to move up and down and rotate;
a cleaning nozzle head attached to the nozzle arm and configured to spray a cleaning solution onto the substrate; and
a nozzle unit coupled to the cleaning nozzle head,
wherein the nozzle unit includes an ionization unit and a discharge unit,
wherein the ionization unit includes:
an outer cylinder, an intermediate cylinder, and an inner cylinder that are arranged in a concentric structure;
a first electrode plate on an inner surface of the outer cylinder;
a second electrode plate and a third electrode plate on an outer surface and an inner surface of the intermediate cylinder, respectively;
a fourth electrode plate on an outer surface of the inner cylinder; and
a first gas inlet, wherein a hydrocarbon-based gas is configured to flow through the first gas inlet into a space between the outer cylinder and the intermediate cylinder, and
wherein the first electrode plate, the second electrode plate, the third electrode plate, and the fourth electrode plate are arranged to cross each other to form a discharge path,
wherein the discharge unit includes:
a plurality of tapered structures connected to a lower end of the ionization unit and having gradually decreasing cross-sectional areas;
a low-reactivity gas receiving unit on a side of the plurality of tapered structures and configured to receive a low-reactivity gas recombined during an ionization process; and
a second gas inlet extending into the inner cylinder, wherein an inert gas is configured to flow through the second gas inlet into the inner cylinder,
wherein each tapered structure of the plurality of tapered structures includes a second opening located in an upper portion of the tapered structure and a first opening located in a lower portion of the tapered structure, and a diameter of the first opening is smaller than a diameter of the second opening,
wherein a hydrocarbon series gas configured to flow through the first gas inlet is ionized by a discharge occurring between electrode plates having different polarities in the ionization unit, and
wherein the plurality of tapered structures are configured to increase a velocity of the inert gas being introduced through the second gas inlet, thereby decreasing a pressure of the inert gas and causing the ionized gas to be sprayed onto a surface of the substrate to perform surface activation treatment.
